(19) United States
(12) Patent Application Publication
(10) Pub. No.: US 2026/0334215 A1
(43) Pub. Date: Oct. 22, 2026

(54) SEMICONDUCTOR INTEGRATED CIRCUIT DEVICE

(71) Applicant: Socionext Inc., Kanagawa (JP)

(72) Inventor: Masachika ONO, Yokohama-shi (JP)

(21) Appl. No.: 19/710,876

(22) Filed: Jun. 17, 2026

Related U.S. Application Data
(63) Continuation of application No. PCT/JP2024/028725, filed on Aug. 9, 2024.

(30) Foreign Application Priority Data
Dec. 27, 2023 (JP) 2023-220745

(51) Int. Cl. H10W 20/40; H10D 30/00; H10D 30/43; H10D 62/10; H10D 84/80; H10W 20/41; H10W 20/42; H10W 20/43

(52) U.S. Cl. CPC H10W 20/496; H10D 30/43; H10D 30/502; H10D 62/121; H10D 84/813; H10W 20/422; H10W 20/427; H10W 20/43; H10W 20/435

(57) ABSTRACT

A layout structure of a capacitor cell using CFETs and back-side interconnects is provided. The capacitor cell includes first nanosheet FETs and second nanosheet FETs formed above the first nanosheet FETs. A power supply line supplying VDD extends in the X direction in a back-side interconnect layer and overlaps the first nanosheet FETs in planar view. The power supply line is connected to the sources of the first nanosheet FETs through vias provided at positions overlapping in planar view. A power supply line supplying VSS is connected to gate interconnects.

### CROSS-REFERENCE TO RELATED APPLICATIONS

This is a continuation of International Application No. PCT/JP2024/028725 filed on Aug. 9, 2024, which claims priority to Japanese Patent Application No. 2023-220745 filed on Dec. 27, 2023. The entire disclosures of these applications are incorporated by reference herein.

### BACKGROUND

The present disclosure relates to a semiconductor integrated circuit device provided with standard cells having complementary FETs (CFETs).

As a method for forming a semiconductor integrated circuit on a semiconductor substrate, a standard cell method is known. The standard cell method is a method in which basic units (e.g., inverters, latches, flipflops, and full adders) having specific logical functions are prepared in advance as standard cells, and a plurality of such standard cells are placed on a semiconductor substrate and connected through interconnects, whereby an LSI chip is designed.

Also, as for a transistor, which is a basic constituent of an LSI, improvement in integration degree, reduction in operating voltage, and improvement in operating speed have been achieved by reducing (scaling) the gate length. In recent years, however, increase in off current due to excessive scaling and the resulting significant increase in power consumption have raised problems. To solve the problems, three-dimensional transistors, of which the transistor structure has changed from the conventional planar structure to a three-dimensional structure, have been vigorously studied.

WO 2020/110733 (Patent Document 1) discloses a capacitor cell using CFETs.

US Patent Application Publication No. 2022/0123023 (Patent Document 2) discloses standard cell using CFETs, in which interconnects are provided on the back immediately below the transistors and the sources/drains of the transistors are connected to the interconnects.

However, no examination has been made so far on the layout structure of a capacitor cell in which, in CFETs, interconnects are provided on the back immediately below the transistors.

An objective of the present disclosure is providing a layout structure of a capacitor cell in which, in CFETs, interconnects are provided on the back immediately below the transistors.

### SUMMARY

A semiconductor integrated circuit device according to the first mode of the disclosure includes a standard cell serving as a capacitor cell, wherein the standard cell includes a first nanosheet field effect transistor (FET) of a first conductivity type including a first nanosheet extending in a first direction, a second nanosheet FET of a second conductivity type formed above the first nanosheet FET in a depth direction, and including a second nanosheet extending in the first direction and overlapping the first nanosheet in planar view, a gate interconnect extending in a second direction perpendicular to the first direction, overlapping the first and second nanosheets in planar view, and surrounding peripheries of the first and second nanosheets in the second direction and the depth direction, a first power supply line formed in a first interconnect layer located on the back side of the first nanosheet FET, extending in the first direction, overlapping the first nanosheet FET in planar view, and supplying a first power supply voltage, and a second power supply line connected to the gate interconnect and supplying a second power supply voltage, and the first power supply line is connected to a source of the first nanosheet FET through a first via provided at a position overlapping the first power supply line and the first nanosheet FET in planar view.

According to the above mode, the standard cell serving as a capacitor cell includes a first nanosheet FET and a second nanosheet FET formed above the first nanosheet FET. A first power supply line supplying a first power supply voltage extends in a first direction in a first interconnect layer located on the back side and overlaps the first nanosheet FET in planar view. A second power supply line supplying a second power supply voltage is connected to a gate interconnect serving as the gates of the first and second nanosheet FETs. The first power supply line is connected to the source of the first nanosheet FET through a first via provided at a position overlapping in planar view. With this, a capacitor is formed in the first nanosheet FET through a gate oxide film. In this way, a layout structure of a capacitor cell using the CFET and the back-side interconnect is achieved.

A semiconductor integrated circuit device according to the second mode of the disclosure includes: a first standard cell serving as a capacitor cell; and second and third standard cells having a logical function, placed in a same cell row as the first standard cell, wherein the first standard cell includes a first nanosheet field effect transistor (FET) of a first conductivity type including a first nanosheet extending in a first direction, a second nanosheet FET of a second conductivity type formed above the first nanosheet FET in a depth direction, and including a second nanosheet extending in the first direction and overlapping the first nanosheet in planar view, a gate interconnect extending in a second direction perpendicular to the first direction, overlapping the first and second nanosheets in planar view, and surrounding peripheries of the first and second nanosheets in the second direction and the depth direction, a first power supply line formed in a first interconnect layer located on the back side of the first nanosheet FET, extending in the first direction, overlapping the first nanosheet FET in planar view, and supplying a first power supply voltage, and a second power supply line connected to the gate interconnect and supplying a second power supply voltage, the first power supply line is connected to a source of the first nanosheet FET through a first via provided at a position overlapping the first power supply line and the first nanosheet FET in planar view, the second standard cell includes a third nanosheet FET of the first conductivity type, formed at a same position as the first nanosheet FET in the depth direction, and including a third nanosheet extending in the first direction, the third standard cell includes a fourth nanosheet FET of the first conductivity type, formed at a same position as the first nanosheet FET in the depth direction, and including a fourth nanosheet extending in the first direction, the third nanosheet is the same in size in the second direction and also the same in placement range in the second direction as the first nanosheet, and the fourth nanosheet is smaller in size in the second direction than the first nanosheet.

According to the above mode, a third nanosheet FET of the second standard cell and a fourth nanosheet FET of the third standard cell are formed at the same position in the depth direction as the first nanosheet FET of the first standard cell serving as a capacitor cell. A third nanosheet of the third nanosheet FET is the same in size and placement range in the second direction as the first nanosheet of the first nanosheet FET. A fourth nanosheet of the fourth nanosheet FET is smaller in size in the second direction than the first nanosheet. Therefore, the distances of the active regions of the second and third standard cells from the active regions adjacent in the first direction are fixed. This can improve the estimation precision of the performance.

According to the present disclosure, it is possible to provide a layout structure of a capacitor cell in which, in CFETs, interconnects are provided on the back immediately below the transistors.

### BRIEF DESCRIPTION OF THE DRAWINGS

FIGS. 1A and 1B are plan views showing a layout structure example of a capacitor cell according to the first embodiment.

FIGS. 2A, 2B, and 2C are cross-sectional views of the layout structure of FIGS. 1A-1B.

FIG. 3 is a circuit diagram of the capacitor cell of FIGS. 1A-1B.

FIGS. 4A-4D are plan views showing layout structure examples of inverter cells, in which FIGS. 4A and 4B show a cell 1 and FIGS. 4C and 4D show a cell 2.

FIGS. 5A and 5B are plan views showing a layout example of a circuit block.

FIGS. 6A and 6B are plan views showing a layout structure example of a capacitor cell according to Alteration 1 of the first embodiment.

FIG. 7 is a cross-sectional view of the layout structure of FIGS. 6A-6B.

FIG. 8 is a circuit diagram of the capacitor cell of FIGS. 6A-6B.

FIGS. 9A and 9B are plan views showing a layout structure example of a capacitor cell according to Alteration 2 of the first embodiment.

FIG. 10 is a circuit diagram of the capacitor cell of FIGS. 9A-9B.

FIGS. 11A-11D are plan views showing layout structure examples of inverter cells, in which FIGS. 11A and 11B show a cell 1 and FIGS. 11C and 11D show a cell 2.

FIGS. 12A and 12B are plan views showing a layout structure example of a capacitor cell according to the second embodiment.

FIGS. 13A-13D are plan views showing layout structure examples of inverter cells, in which FIGS. 13A and 13B show a cell 1 and FIGS. 13C and 13D show a cell 2.

FIGS. 14A and 14B are plan views showing a layout structure example of a capacitor cell according to Alteration 1 of the second embodiment.

FIGS. 15A and 15B are plan views showing a layout structure example of a capacitor cell according to Alteration 2 of the second embodiment.

### DETAILED DESCRIPTION

Embodiments of the present disclosure will be described hereinafter with reference to the accompanying drawings. In the following embodiments, it is assumed that the semiconductor integrated circuit device includes a plurality of standard cells (hereinafter simply called cells as appropriate), and at least some of the standard cells include CFETs, i.e., three-dimensional devices in which p-type FETs and n-type FETs, both having a three-dimensional structure, are laid one upon the other in the direction normal to the substrate. In the embodiments, the CFETs are assumed to include nanosheet FETs.

Note that, in the plan views and the cross-sectional views in the embodiments, illustration of various insulating films and the like may be omitted. Also, as used herein, an expression indicating that sizes such as widths are identical, like the “same wiring width,” is to be understood as including a range of manufacturing variations.

As used herein, “VDD” and “VSS” are used to refer to the power supply voltages or the power supplies themselves.

### First Embodiment

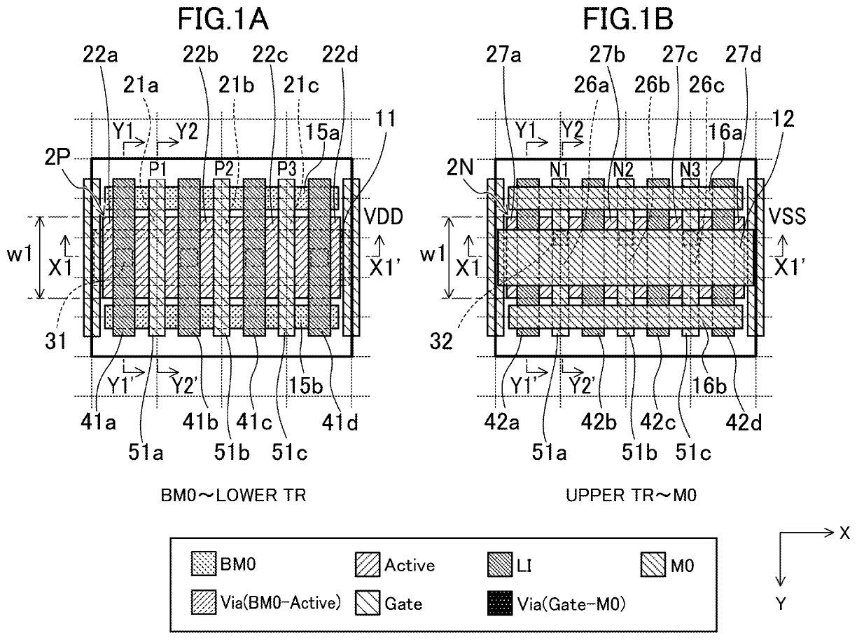

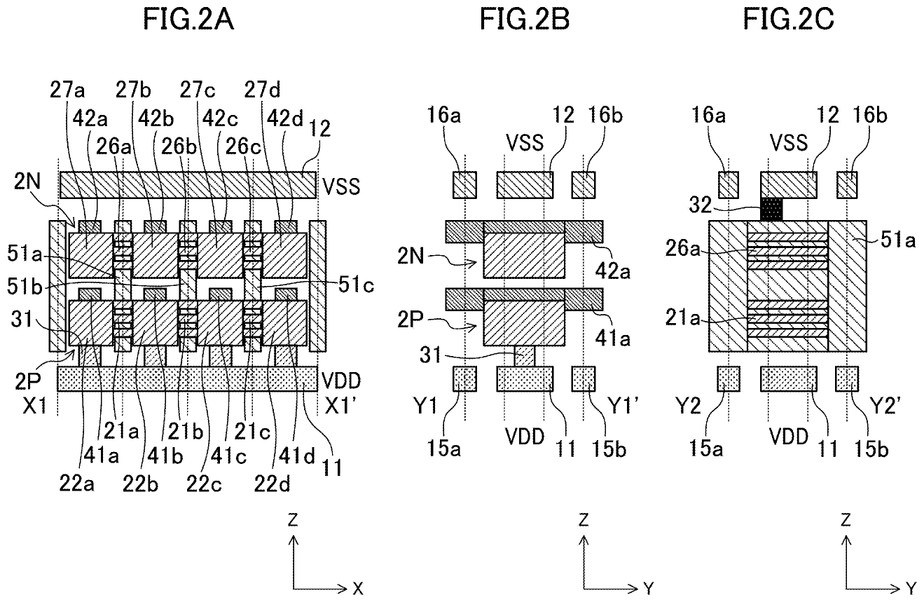

FIGS. 1A-1B and 2A-2C are views showing a layout structure example of a capacitor cell according to the first embodiment, in which FIGS. 1A and 1B show plan views, FIG. 2A shows a cross-sectional view taken horizontally in planar view, and FIGS. 2B and 2C are cross-sectional views taken vertically in planar view. The capacitor cell shown in FIGS. 1A-1B and 2A-2C include CFETs. FIG. 1A shows a lower part, i.e., a part including p-type nanosheet FETs formed on the side closer to the substrate and a BM0 interconnect layer that is an interconnect layer on the back side of the FETs. FIG. 1B shows an upper part, i.e., a part including n-type nanosheet FETs formed on the side farther from the substrate and an M0 interconnect layer that is an interconnect layer on the front side of the FETs. FIG. 2A shows a cross section taken along line X1-X1′, FIG. 2B shows a cross section taken along line Y1-Y1′, and FIG. 2C shows a cross section taken along line Y2-Y2′. As used herein, the front side of nanosheet FETs refers to the side, with respect to the nanosheet FETs, on which local interconnects and metal interconnects connected to the nanosheet FETs are stacked one upon another, and the back side of nanosheet FETs refers to the side, with respect to the nanosheet FETs, opposite to the side on which local interconnects and metal interconnects connected to the nanosheet FETs are stacked one upon another.

Note that, in the plan views such as FIGS. 1A-1B, the horizontal direction in the figure is hereinafter referred to as an X direction (corresponding to the first direction), the vertical direction in the figure as a Y direction (corresponding to the second direction), and the direction normal to the substrate plane as a Z direction (corresponding to the depth direction). Also, the dot lines running horizontally and vertically in the plan views such as FIGS. 1A-1B and the dot lines running vertically in the cross-sectional views such as FIGS. 2A-2C represent grid lines used for placement of components at the time of designing. The grid lines are arranged at an equal spacing in the X direction and also arranged at an equal spacing in the Y direction. The grid spacings in the X direction and the Y direction may be the same or different from each other. The grid spacings may also be different among layers. Also, it is not necessarily required to place components on the grid lines. However, from the standpoint of curbing manufacturing variations, it is preferable to place components on the grid lines.

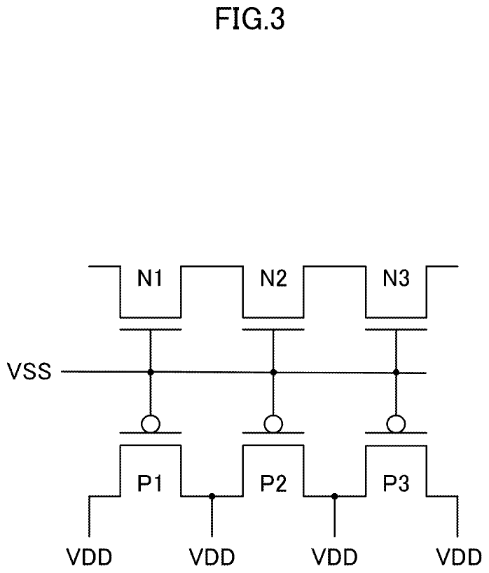

FIG. 3 is a circuit diagram of the capacitor cell shown in FIGS. 1A-1B and 2A-2C. As shown in FIG. 3, the cell shown in FIGS. 1A-1B and 2A-2C has p-type transistors P1, P2, and P3 and n-type transistors N1, N2, and N3. The gates of the p-type transistors P1, P2, and P3 and the n-type transistors N1, N2, and N3 are connected in common to VSS. The sources and drains of the p-type transistors P1, P2, and P3 are connected to VDD. The sources and drains of the n-type transistors N1, N2, and N3 are floating.

In the p-type transistors P1, P2, and P3, capacitors are formed between the gates connected to VSS and the sources and the drains connected to VDD through gate oxide films. The n-type transistors N1, N2, and N3 are in the OFF state, which are therefore dummy transistors.

As shown in FIG. 1A, in the BM0 interconnect layer, a power supply line 11 extending in the X direction is formed. The power supply line 11 supplies VDD. The power supply line 11 is located in the center of the capacitor cell in the Y direction in planar view. In the BM0 interconnect layer, also, an interconnect 15a extending in the X direction is formed on the upper side of the power supply line 11 as viewed in the figure, and an interconnect 15b extending in the X direction is formed on the lower side of the power supply line 11 as viewed in the figure. The interconnects 15a and 15b are dummy interconnects that are floating. It is not necessarily required to form the interconnects 15a and 15b.

Above the power supply line 11, formed is an active region 2P that forms the channels, sources, and drains of p-type nanosheet FETs serving as the p-type transistors P1, P2, and P3. The active region 2P overlaps the power supply line 11 in planar view. The active region 2P includes nanosheets 21a, 21b, and 21c that serve as the channels of the p-type nanosheet FETs. Also, in the active region 2P, portions 22a, 22b, 22c, and 22d that serve as the sources or drains of the p-type nanosheet FETs are connected to the power supply line 11 through vias 31 formed on the back of the portions. The vias 31 overlap the power supply line 11 and the active region 2P in planar view.

Local interconnects 41a, 41b, 41c, and 41d extending in the Y direction are formed. The local interconnects 41a, 41b, 41c, and 41d are respectively in contact with the portions 22a, 22b, 22c, and 22d in the active region 2P.

As shown in FIG. 1B, in the M0 interconnect layer, a power supply line 12 extending the X direction is formed. The power supply line 12 supplies VSS. The power supply line 12 is located in the center of the capacitor cell in the Y direction, and overlaps the power supply line 11, in planar view. Note that, while the line widths of the power supply lines 11 and 12 are illustrated as being the same in FIG. 1, they are not necessarily required to be the same. In the M0 interconnect layer, also, an interconnect 16a extending in the X direction is formed on the upper side of the power supply line 12 as viewed in the figure, and an interconnect 16b extending in the X direction is formed on the lower side of the power supply line 12 as viewed in the figure. The interconnects 16a and 16b are dummy interconnects that are floating. It is not necessarily required to form the interconnects 16a and 16b.

Below the power supply line 12, formed is an active region 2N that forms the channels, sources, and drains of n-type nanosheet FETs serving as the n-type transistors N1, N2, and N3. The active region 2N overlaps the power supply line 12 in planar view. The active region 2N also overlaps the active region 2P in planar view. The active region 2N includes nanosheets 26a, 26b, and 26c that serve as the channels of the n-type nanosheet FETs. The nanosheets 26a, 26b, and 26c of the n-type nanosheet FETs respectively overlap the nanosheets 21a, 21b, and 21c of the p-type nanosheet FETs in planar view.

The size of the active regions 2P and 2N in the Y direction is w1.

Local interconnects 42a, 42b, 42c, and 42d extending in the Y direction are formed. The local interconnects 42a, 42b, 42c, and 42d are respectively in contact with portions 27a, 27b, 27c, and 27d that serve as the sources or drains of the n-type nanosheet FETs in the active region 2N.

Gate interconnects 51a, 51b, and 51c extend in the Y direction and also extend in the Z direction from the upper part over to the lower part. The gate interconnect 51a surrounds the peripheries of the nanosheets 21a and 26a in the Y direction and the Z direction through gate insulating films (not shown). The gate interconnect 51a serves as the gates of the transistors P1 and N1. The gate interconnect 51b surrounds the peripheries of the nanosheets 21b and 26b in the Y direction and the Z direction through gate insulating films (not shown). The gate interconnect 51b serves as the gates of the transistors P2 and N2. The gate interconnect 51c surrounds the peripheries of the nanosheets 21c and 26c in the Y direction and the Z direction through gate insulating films (not shown). The gate interconnect 51c serves as the gates of the transistors P3 and N3.

The gate interconnects 51a, 51b, and 51c are connected to the power supply line 12 through vias 32 formed on the front thereof. The vias 32 overlap the power supply line 12 and the active region 2N in planar view, and are formed in end portions, in the Y direction, of overlap regions of the power supply line 12 and the respective nanosheets 26a, 26b, and 26c, i.e., formed at positions closest to ends of the overlap regions.

In the capacitor cell according to this embodiment, the portions 22a, 22b, 22c, and 22d serving as the sources or drains of the p-type transistors P1, P2, and P3 are supplied with VDD from the power supply line 11 formed in the BM0 interconnect layer through the vias 31 overlapping the power supply line 11 and the active region 2P in planar view. Therefore, the path length from the power supply line 11 to the portions 22a, 22b, 22c, and 22d is small. Since this can reduce the resistance values from the power supply line 11 to the nanosheets 21a, 21b, and 21c, the high-speed response property of the capacitors formed can be improved.

Also, in the capacitor cell according to this embodiment, the gate interconnects 51a, 51b, and 51c serving as the gates of the p-type transistors P1, P2, and P3 are supplied with VSS from the power supply line 12 formed in the M0 interconnect layer through the vias 32. The vias 32 are formed in end portions, in the Y direction, of the overlap regions of the power supply line 12 and the respective nanosheets 26a, 26b, and 26c. Since this can reduce the resistance values from the power supply line 12 to the gates surrounding the nanosheets 21a, 21b, and 21c, the high-speed response property of the capacitors formed can be improved.

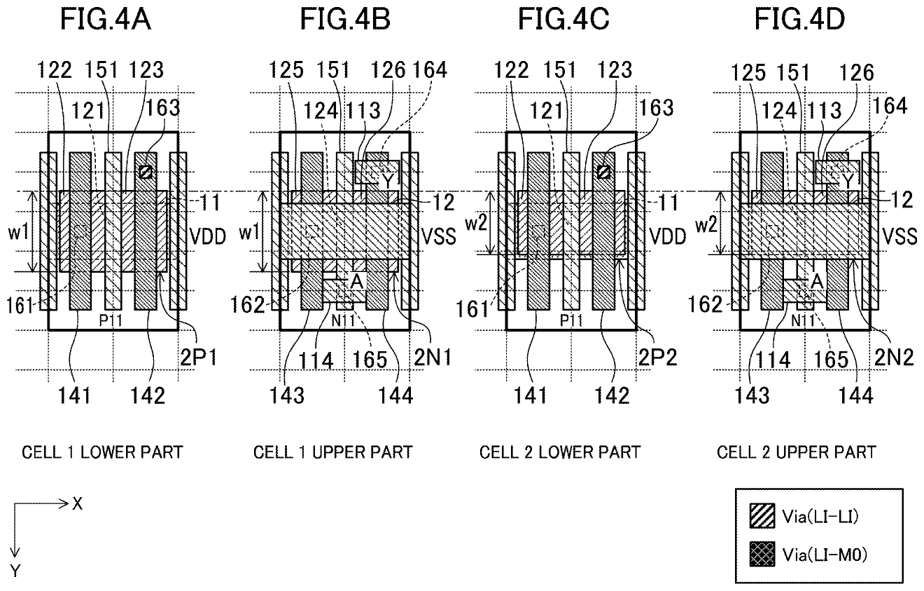

FIGS. 4A-4D are plan views showing layout structure examples of inverter cells according to this embodiment, in which FIG. 4A shows a lower part of an inverter cell 1, FIG. 4B shows an upper part of the inverter cell 1, FIG. 4C shows a lower part of an inverter cell 2, and FIG. 4D shows an upper part of the inverter cell 2. The inverter cell is an example of logic cell.

Each of the inverter cells 1 and 2 includes a p-type transistor P11 and an n-type transistor N11, and constitutes an inverter circuit having an input A and an output Y. The p-type transistor P11 is formed in the lower part and the n-type transistor N11 is formed in the upper part. The inverter cell 1 and the inverter cell 2 have roughly the same layout structure, except that active regions 2P1 and 2N1 of the inverter cell 1 and active regions 2P2 and 2N2 of the inverter cell 2 are different in size and position in the Y direction from each other.

As shown in FIGS. 4A and 4C, a power supply line 11 extending in the X direction is formed in the BM0 interconnect layer. The power supply line 11 supplies VDD. The power supply line 11 is located in the center of the inverter cells 1 and 2 in the Y direction in planar view.

Above the power supply line 11, formed are active regions 2P1 and 2P2 each of which forms the channel, source, and drain of a p-type nanosheet FET serving as the p-type transistor P11. The active regions 2P1 and 2P2 overlap the power supply line 11 in planar view. Each of the active regions 2P1 and 2P2 includes a nanosheet 121 serving as the channel of the p-type nanosheet FET and portions 122 and 123 serving as the source or drain of the p-type nanosheet FET. The portion 122 is connected to the power supply line 11 through a via 161 formed on the back of the portion.

Local interconnects 141 and 142 extending in the Y direction are formed. The local interconnects 141 and 142 are respectively in contact with the portions 122 and 123 in each of the active regions 2P1 and 2P2.

As shown in FIGS. 4B and 4D, a power supply line 12 extending in the X direction is formed in the M0 interconnect layer. The power supply line 12 supplies VSS. The power supply line 12 is located in the center of the inverter cells 1 and 2 in the Y direction in planar view. Also, in the M0 interconnect layer, an interconnect 113 extending in the X direction is formed on the upper side of the power supply line 12 as viewed in the figure, and an interconnect 114 extending in the X direction is formed on the lower side of the power supply line 12 as viewed in the figure. The interconnect 113 corresponds to the output Y and the interconnect 114 corresponds to the input A.

Below the power supply line 12, formed are active regions 2N1 and 2N2 each of which forms the channel, source, and drain of an n-type nanosheet FET serving as the n-type transistor N11. The active regions 2N1 and 2N2 overlap the power supply line 12 in planar view. Each of the active regions 2N1 and 2N2 includes a nanosheet 124 serving as the channel of the n-type nanosheet FET and portions 125 and 126 serving as the source or drain of the n-type nanosheet FET.

Local interconnects 143 and 144 extending in the Y direction are formed. The local interconnects 143 and 144 are respectively in contact with the portions 125 and 126 in each of the active regions 2N1 and 2N2. The local interconnect 143 is connected to the power supply line 12 through a via 162. The local interconnect 144 is connected to the local interconnect 142 through a via 163 and also connected to the interconnect 113 through a via 164.

A gate interconnect 151 extends in the Y direction and also extends in the Z direction from the upper part over to the lower part. The gate interconnect 151 surrounds the peripheries of the nanosheets 121 and 124 in the Y direction and the Z direction through gate insulating films (not shown). The gate interconnect 151 serves as the gates of the transistors P11 and N11. The gate interconnect 151 is connected to the interconnect 114 through a via 165.

In the inverter cell 1, the size of the active regions 2P1 and 2N1 in the Y direction is w1. In the inverter cell 2, the size of the active regions 2P2 and 2N2 in the Y direction is w2 that is smaller than w1 (w1>w2). Therefore, the drive capability of the inverter cell 1 is larger than the drive capability of the inverter cell 2. Also, in the inverter cells 1 and 2, the positions of the upper ends, as viewed in the figure, of the active regions 2P1, 2N1, 2P2, and 2N2 in the Y direction are aligned.

On the other hand, as described above, in the capacitor cell according to this embodiment, the size of the active regions 2P and 2N in the Y direction is w1 that is the same as the size of the active regions 2P1 and 2N1 of the inverter cell 1 in the Y direction. Also, in the capacitor cell according to this embodiment, the placement range of the active regions 2P and 2N in the Y direction is the same as the placement range of the active regions 2P1 and 2N1 of the inverter cell 1 in the Y direction.

That is, the nanosheets 121 and 124 of the inverter cell 1 are the same in size in the Y direction, and also the same in placement range in the Y direction, as the nanosheets 21a, 21b, 21c, 26a, 26b, and 26c of the capacitor cell. The nanosheets 121 and 124 of the inverter cell 2 are smaller in size in the Y direction than the nanosheets 21a, 21b, 21c, 26a, 26b, and 26c of the capacitor cell. In addition, the positions of the upper ends, as viewed in the figure, in the Y direction of the nanosheets 121 and 124 of the inverter cells 1 and 2 and the nanosheets 21a, 21b, 21c, 26a, 26b, and 26c of the capacitor cell are the same.

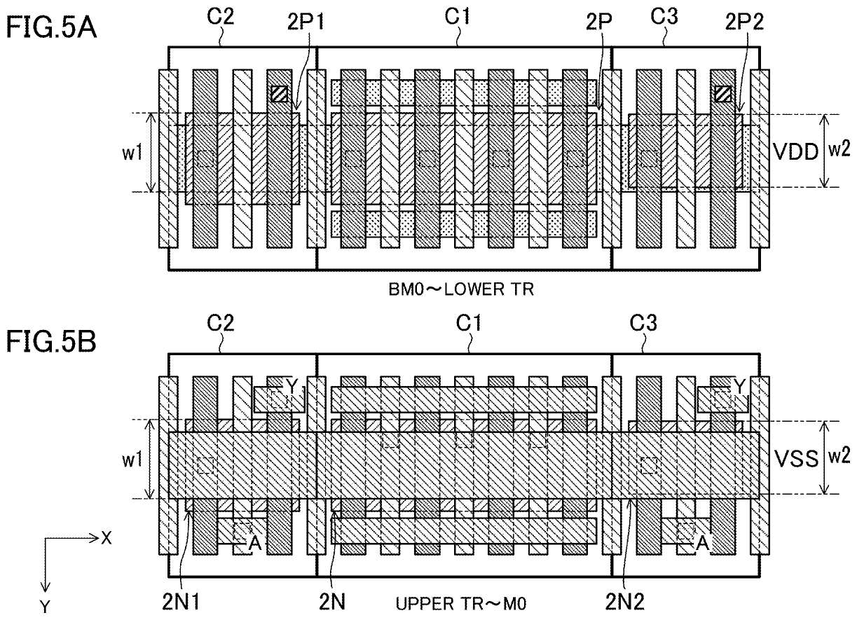

FIGS. 5A-5B are plan views showing a layout example of a circuit block, in which FIG. 5A shows a lower part and FIG. 5B shows an upper part. In the layout of FIGS. 5A-5B, a capacitor cell C1 according to this embodiment is placed in the center, and inverter cells C2 and C3 are placed on both sides. The inverter cell C2 on the left of the capacitor cell in the figure is the inverter cell 1 shown in FIGS. 4A and 4B, and the inverter cell C3 on the right of the capacitor cell in the figure is the inverter cell 2 shown in FIGS. 4C and 4D.

As shown in FIGS. 5A-5B, the active regions 2P and 2N of the capacitor cell C1 and the active regions 2P1 and 2N1 of the inverter cell C2 have the same size w1 in the Y direction, and the size w2 of the active regions 2P2 and 2N2 of the inverter cell C3 in the Y direction is smaller than the size of the active regions 2P and 2N of the capacitor cell C1 in the Y direction. Also, in the capacitor cell C1 and the inverter cells C2 and C3, the positions of the upper ends, as viewed in the figure, in the Y direction of the active regions 2P, 2P1, 2P2, 2N, 2N1, and 2N2 are aligned.

Therefore, for the active regions 2P1 and 2N1 of the inverter cell C2, the active regions 2P and 2N of the adjacent capacitor cell C1 are present over the entire range in the Y direction. Also, for the active regions 2P2 and 2N2 of the inverter cell C3, the active regions 2P and 2N of the adjacent capacitor cell C1 are present over the entire range in the Y direction. That is, the distances of the active regions 2P1, 2N1, 2P2, and 2N2 of the inverter cells C2 and C3 from the adjacent active regions in the X direction are fixed. This can improve the estimation precision of the performance of the inverter cells 1 and 2.

### Alteration 1

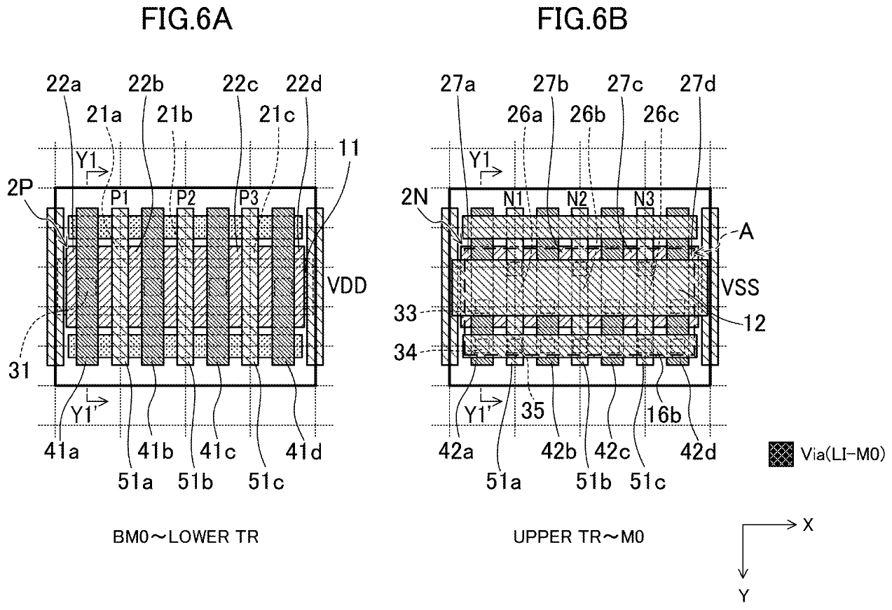

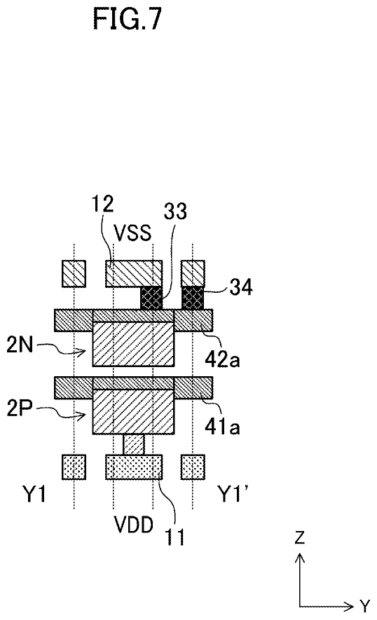

FIGS. 6A-6B are plan views showing a layout structure example of a capacitor cell according to Alteration 1 of this embodiment, in which FIG. 6A shows a lower part and FIG. 6B shows an upper part. FIG. 7 is a cross-sectional view taken along line Y1-Y1′ in FIGS. 6A-6B.

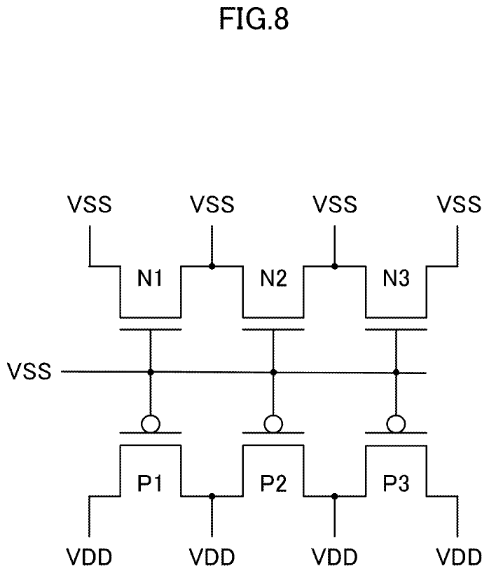

FIG. 8 is a circuit diagram of the capacitor cell shown in FIGS. 6A, 6B, and 7. The circuit diagram of FIG. 8 is roughly the same as that of FIG. 3, except that the sources and drains of the n-type transistors N1, N2, and N3 are connected to VSS, not floating.

The layout structure according to this alteration is basically the same as the layout structure according to the first embodiment, but vias are additionally provided in area A indicated by the broken line in FIG. 6B.

That is, the local interconnects 42a, 42b, 42c, and 42d are connected to the power supply line 12 through vias 33. Also, the interconnect 16b is connected to the local interconnects 42a, 42b, 42c, and 42d through vias 34, and also connected to the gate interconnects 51a, 51b, and 51c through vias 35.

According to this alteration, capacitors are also formed between the local interconnects 42a, 42b, 42c, and 42d and the portions 27a, 27b, 27c, and 27d in the active region 2N in the upper part and the local interconnects 41a, 41b, 41c, and 41d and the portions 22a, 22b, 22c, and 22d in the active region 2P in the lower part. This can increase the capacitance value of the capacitor cell.

Moreover, VSS is supplied to the gate interconnects 51a, 51b, and 51c also from the interconnect 16b. This can reduce the resistance values from the power supply line 12 to the gates surrounding the nanosheets 21a, 21b, and 21c.

### Alteration 2

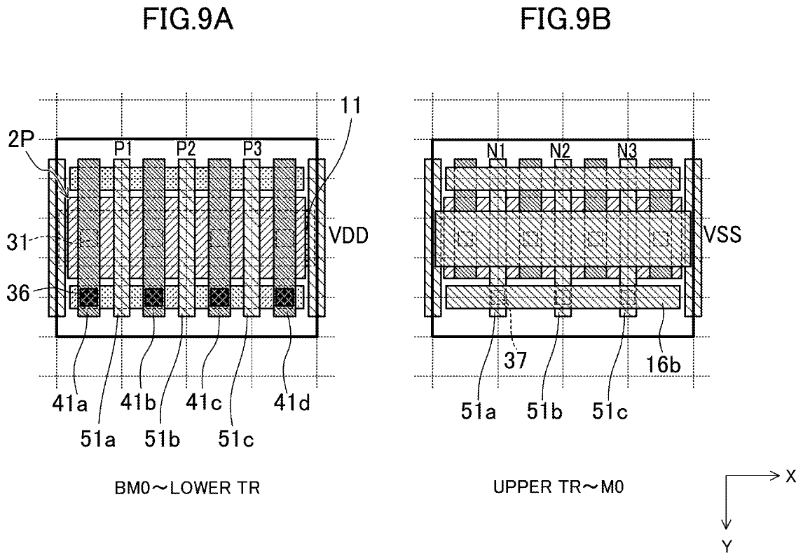

FIGS. 9A-9B are plan views showing a layout structure example of a capacitor cell according to Alteration 2 of this embodiment, in which FIG. 9A shows a lower part and FIG. 9B shows an upper part.

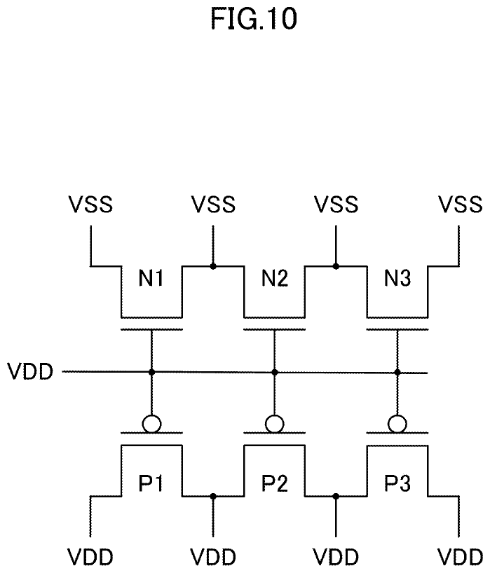

FIG. 10 is a circuit diagram of the capacitor cell shown in FIGS. 9A-9B. The circuit diagram of FIG. 10 is roughly the same as that of FIG. 8, except that the gates of the p-type transistors P1, P2, and P3 and the n-type transistors N1, N2, and N3 are connected to VDD, not VSS. That is, in this alteration, the n-type transistors N1, N2, and N3 form capacitors. The p-type transistors P1, P2, and P3 are in the OFF state, which are therefore dummy transistors.

As shown in FIGS. 9A-9B, the local interconnects 41a, 41b, 41c, and 41d in the lower part are connected to the M0 interconnect 16b in the upper part through vias 36. The M0 interconnect 16b is connected to the gate interconnects 51a, 51b, and 51c through vias 37. Therefore, the gate interconnects 51a, 51b, and 51c are supplied with VDD from the power supply line 11 in the BM0 interconnect layer through the vias 31, the active region 2P, the local interconnects 41a, 41b, 41c, and 41d, the vias 36, the M0 interconnect 16b, and the vias 37.

### Alteration 3

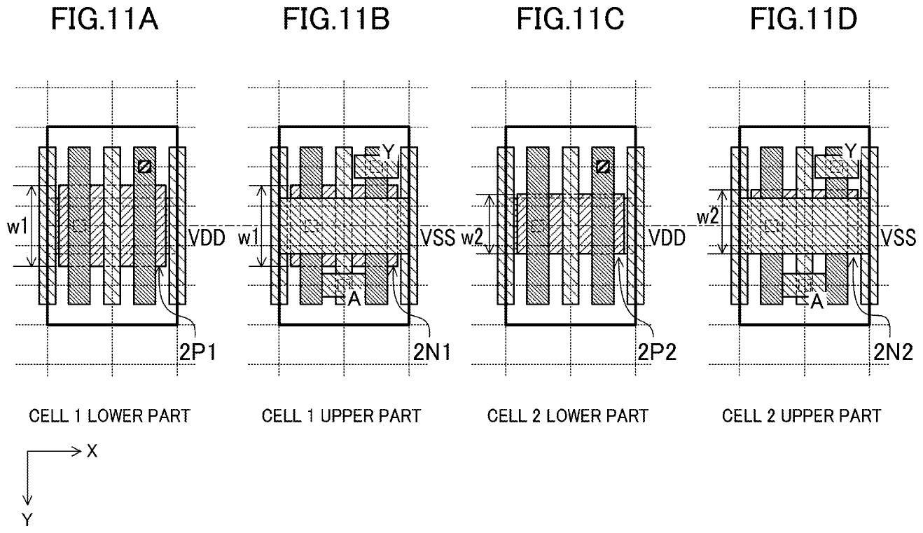

FIGS. 11A-11D are plan views showing layout structure examples of inverter cells according to this alteration, in which FIG. 11A shows a lower part of an inverter cell 1, FIG. 11B shows an upper part of the inverter cell 1, FIG. 11C shows a lower part of an inverter cell 2, and FIG. 11D shows an upper part of the inverter cell 2.

The layout structure shown in FIGS. 11A-11D is roughly the same as the layout structure shown in FIGS. 4A-4D, except that the center position of the active regions 2P2 and 2N2 of the inverter cell 2 in the Y direction is aligned with the center position of the active regions 2P1 and 2N1 of the inverter cell 1.

In this alteration, also, when the capacitor cell of this embodiment is placed adjacent t the inverter cells 1 and 2, the active regions 2P and 2N of the adjacent capacitor cell are present over the entire range in the Y direction for the active regions 2P1, 2N1, 2P2, and 2N2 of the inverter cells 1 and 2. That is, the distances of the active regions 2P1, 2N1, 2P2, and 2N2 of the inverter cells 1 and 2 from the active regions adjacent in the X direction are fixed. This can improve the estimation precision of the performance of the inverter cells 1 and 2.

Note that the above effect is not limited to this alteration, but a similar effect can also obtained as far as the active regions 2P2 and 2N2 of the inverter cell 2 are placed within the range of the active regions 2P1 and 2N1 of the inverter cell 1 in the Y direction.

### Second Embodiment

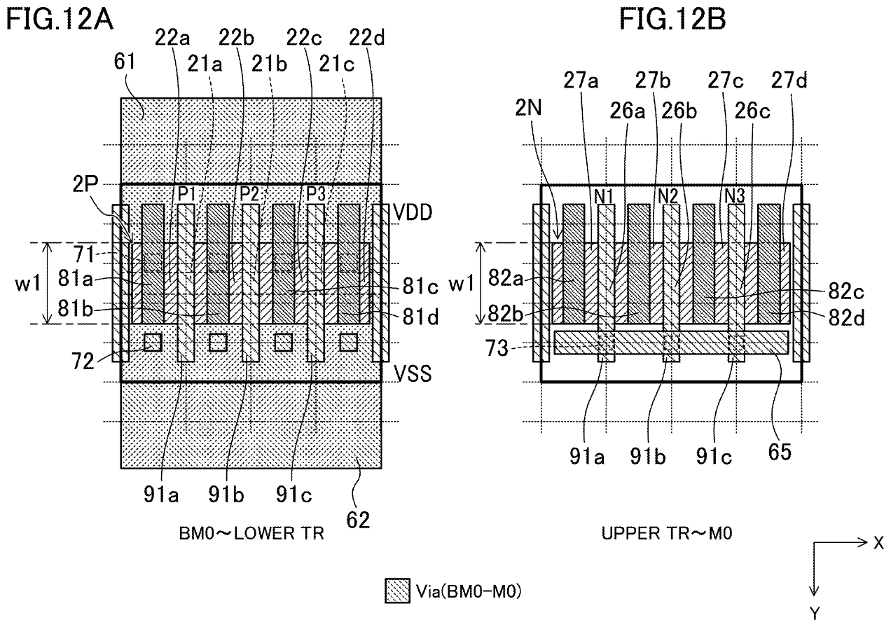

FIGS. 12A-12B are plan views showing a layout structure example of a capacitor cell according to the second embodiment, in which FIG. 12A shows a lower part and FIG. 12B shows an upper part. The circuit diagram of the capacitor cell shown in FIGS. 12A-12B is the same as that of FIG. 3: i.e., the p-type transistors P1, P2, and P3 form capacitors.

As shown in FIG. 12A, in the BM0 interconnect layer, power supply lines 61 and 62 extending in the X direction are formed. The power supply line 61 supplies VDD, and the power supply line 62 supplies VSS. The power supply line 61 is placed on the upper side of the capacitor cell as viewed in the figure, and the power supply line 62 is placed on the lower side of the capacitor cell as viewed in the figure.

Above the power supply lines 61 and 62, formed is an active region 2P that forms the channels, sources, and drains of p-type nanosheet FETs serving as the p-type transistors P1, P2, and P3. The active region 2P overlaps the power supply lines 61 and 62 in planar view. The active region 2P includes nanosheets 21a, 21b, and 21c serving as the channels of the p-type nanosheet FETs. Also, in the active region 2P, portions 22a, 22b, 22c, and 22d serving as the sources or drains of the p-type nanosheet FETs are connected to the power supply line 61 through vias 71 formed on the back of the portions.

The size of the active regions 2P and 2N in the Y direction is w1.

Local interconnects 81a, 81b, 81c, and 81d extending in the Y direction are formed. The local interconnects 81a, 81b, 81c, and 81d are respectively in contact with the portions 22a, 22b, 22c, and 22d in the active region 2P.

As shown in FIG. 12B, formed is an active region 2N that forms the channels, sources, and drains of n-type nanosheet FETs serving as the n-type transistors N1, N2, and N3. The active region 2N overlaps the active region 2P in planar view. The active region 2N includes nanosheets 26a, 26b, and 26c serving as the channels of the n-type nanosheet FETs.

In the M0 interconnect layer, an interconnect 65 extending in the X direction is formed. The interconnect 65 is placed on the lower side of the active region 2N as viewed in the figure, and is connected to the power supply line 62 through vias 72.

Local interconnects 82a, 82b, 82c, and 82d extending in the Y direction are formed. The local interconnects 82a, 82b, 82c, and 82d are respectively in contact with portions 27a, 27b, 27c, and 27d serving as the sources or drains of the n-type nanosheet FETs in the active region 2N.

Gate interconnects 91a, 91b, and 91c extend in the Y direction and also extend in the Z direction from the upper part over to the lower part. The gate interconnect 91a surrounds the peripheries of the nanosheets 21a and 26a in the Y direction and the Z direction through gate insulating films (not shown). The gate interconnect 91a serves as the gates of the transistors P1 and N1. The gate interconnect 91b surrounds the peripheries of the nanosheets 21b and 26b in the Y direction and the Z direction through gate insulating films (not shown). The gate interconnect 91b serves as the gates of the transistors P2 and N2. The gate interconnect 91c surrounds the peripheries of the nanosheets 21c and 26c in the Y direction and the Z direction through gate insulating films (not shown). The gate interconnect 91c serves as the gates of the transistors P3 and N3.

The gate interconnects 91a, 91b, and 91c are connected to the M0 interconnect 65 through vias 73 formed on the front thereof.

In the capacitor cell according to this embodiment, the gate interconnects 91a, 91b, and 91c serving as the gates of the p-type transistors P1, P2, and P3 are supplied with VSS from the power supply line 62 formed in the BM0 interconnect layer through the vias 72, the M0 interconnect 65, and the vias 73.

Also, in the capacitor cell according to this embodiment, the portions 22a, 22b, 22c, and 22d serving as the sources or drains of the p-type transistors P1, P2, and P3 are supplied with VDD from the power supply line 61 formed in the BM0 interconnect layer through the vias 71 overlapping the power supply line 61 and the active region 2P in planar view. Therefore, the path length from the power supply line 61 to the portions 22a, 22b, 22c, and 22d is small. Since this can reduce the resistance values from the power supply line 61 to the nanosheets 21a, 21b, and 21c, the high-speed response property of the capacitors formed can be improved.

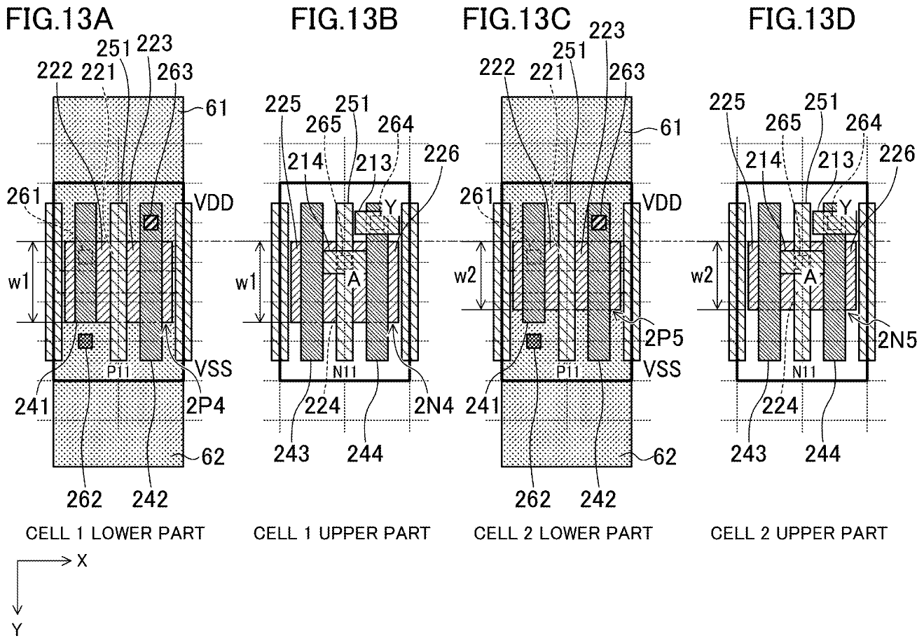

FIGS. 13A-13D are plan views showing layout structure examples of inverter cells according to this embodiment, in which FIG. 13A shows a lower part of an inverter cell 1, FIG. 13B shows an upper part of the inverter cell 1, FIG. 13C shows a lower part of an inverter cell 2, and FIG. 13D shows an upper part of the inverter cell 2.

Each of the inverter cells 1 and 2 includes a p-type transistor P11 and an n-type transistor N11 and constitutes an inverter circuit having an input A and an output Y. The p-type transistor P11 is formed in the lower part and the n-type transistor N11 is formed in the upper part. The inverter cell 1 and the inverter cell 2 have roughly the same layout structure, except that active regions 2P4 and 2N4 of the inverter cell 1 and active regions 2P5 and 2N5 of the inverter cell 2 are different in size and position in the Y direction from each other.

As shown in FIGS. 13A and 13C, power supply lines 61 and 62 extending in the X direction are formed in the BM0 interconnect layer. The power supply line 61 supplies VDD, and the power supply line 62 supplies VSS. The power supply line 61 is placed on the upper side of the inverter cells 1 and 2 as viewed in the figure, and the power supply line 62 is placed on the lower side of the inverter cells 1 and 2 as viewed in the figure.

Above the power supply lines 61 and 62, formed are the active regions 2P4 and 2P5 each of which forms the channel, source, and drain of a p-type nanosheet FET serving as the p-type transistor P11. The active regions 2P4 and 2P5 overlap the power supply lines 61 and 62 in planar view. Each of the active regions 2P4 and 2P5 includes a nanosheet 221 serving as the channel of the p-type nanosheet FET and portions 222 and 223 serving as the source or drain of the p-type nanosheet FET. The portion 222 is connected to the power supply line 61 through a via 261 formed on the back of the portion.

Local interconnects 241 and 242 extending in the Y direction are formed. The local interconnects 241 and 242 are respectively in contact with the portions 222 and 223 in each of the active regions 2P4 and 2P5.

As shown in FIGS. 13B and 13D, formed are active regions 2N4 and 2N5 each of which forms the channel, source, and drain of an n-type nanosheet FET serving as the n-type transistor N11. The active regions 2N4 and 2N5 overlap the power supply lines 61 and 62 in planar view. Each of the active regions 2N4 and 2N5 includes a nanosheet 224 serving as the channel of the n-type nanosheet FET and portions 225 and 226 serving as the source or drain of the n-type nanosheet FET. In the M0 interconnect layer, interconnects 213 and 214 extending in the X direction are formed. The interconnect 213 corresponds to the output Y and the interconnect 214 corresponds to the input A.

Local interconnects 243 and 244 extending in the Y direction are formed. The local interconnects 243 and 244 are respectively in contact with the portions 225 and 226 in each of the active regions 2N4 and 2N5. The local interconnect 243 is connected to the power supply line 62 through a via 262. The local interconnect 244 is connected to the local interconnect 242 through a via 263 and also connected to the interconnect 213 through a via 264.

A gate interconnect 251 extends in the Y direction and also extends in the Z direction from the upper part over to the lower part. The gate interconnect 251 surrounds the peripheries of the nanosheets 221 and 224 in the Y direction and the Z direction through gate insulating films (not shown). The gate interconnect 251 serves as the gates of the transistors P11 and N11. The gate interconnect 251 is connected to the interconnect 214 through a via 265.

In the inverter cell 1, the size of the active regions 2P4 and 2N4 in the Y direction is w1. In the inverter cell 2, the size of the active regions 2P5 and 2N5 in the Y direction is w2 that is smaller than w1 (w1>w2). Therefore, the drive capability of the inverter cell 1 is larger than the drive capability of the inverter cell 2. Also, in the inverter cells 1 and 2, the positions of the upper ends, as viewed in the figure, of the active regions 2P4, 2N4, 2P5, and 2N5 in the Y direction are aligned.

On the other hand, as described above, in the capacitor cell according to this embodiment, the size of the active regions 2P and 2N in the Y direction is w1 that is the same as the size of the active regions 2P4 and 2N4 of the inverter cell 1 in the Y direction. Also, in the capacitor cell according to this embodiment, the placement range of the active regions 2P and 2N in the Y direction is the same as the placement range of the active regions 2P4 and 2N4 of the inverter cell 1 in the Y direction.

That is, the nanosheets 221 and 224 of the inverter cell 1 are the same in size in the Y direction, and also the same in the placement range in the Y direction, as the nanosheets 21a, 21b, 21c, 26a, 26b, and 26c of the capacitor cell. The nanosheets 221 and 224 of the inverter cell 2 are smaller in size in the Y direction than the nanosheets 21a, 21b, 21c, 26a, 26b, and 26c of the capacitor cell. In addition, the positions of the upper ends, as viewed in the figure, of the nanosheets 221 and 224 of the inverter cells 1 and 2 and the nanosheets 21a, 21b, 21c, 26a, 26b, and 26c of the capacitor cell in the Y direction are the same.

Therefore, when the capacitor cell according to this embodiment is placed adjacent to the inverter cells 1 and 2, the active regions 2P and 2N of the adjacent capacitor cell are present over the entire range in the Y direction for the active regions 2P4, 2N4, 2P5, and 2N5 of the inverter cells 1 and 2. That is, the distances of the active regions 2P4, 2N4, 2P5, and 2N5 of the inverter cells 1 and 2 from the active regions adjacent in the X direction are fixed. This can improve the estimation precision of the performance of the inverter cells 1 and 2.

Also, in the capacitor cell and the inverter cells 1 and 2, the upper ends, as viewed in the figure, of the active regions in the Y direction are aligned. With this configuration, the active regions forming the p-type nanosheet FETs can be placed closer to the power supply line 61 supplying VDD that is located on the upper side in the figure. Since this can reduce the resistance at the power supply, a power supply voltage drop can be curbed.

### Alteration 1

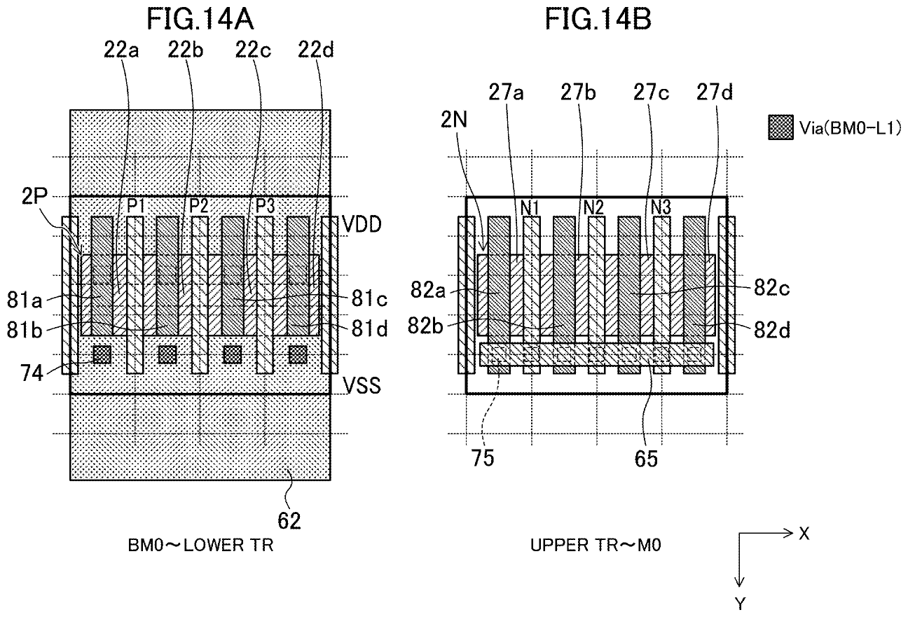

FIGS. 14A-14B are plan views showing a layout structure example of a capacitor cell according to Alteration 1 of this embodiment, in which FIG. 14A shows a lower part and FIG. 14B shows an upper part. The circuit diagram of the capacitor cell shown in FIGS. 14A-14B is the same as that of FIG. 8.

The layout structure according to this alteration is basically the same as the layout structure according to the second embodiment, but as shown in FIG. 14B, in the upper part, the local interconnects 82a, 82b, 82c, and 82d extend up to positions overlapping the M0 interconnect 65 in planar view. The local interconnects 82a, 82b, 82c, and 82d are connected to the power supply line 62 formed in the BM0 interconnect layer through vias 74. Also, the local interconnects 82a, 82b, 82c, and 82d are connected to the M0 interconnect 65 through vias 75.

That is, in this alteration, VSS is supplied from the power supply line 62 to the portions 27a, 27b, 27c, and 27d serving as the sources or drains of the n-type transistors in the active region 2N through the vias 74 and the local interconnects 82a, 82b, 82c, and 82d.

According to this alteration, capacitors are also formed between the local interconnects 82a, 82b, 82c, and 82d and the portions 27a, 27b, 27c, and 27d in the active region 2N in the upper part and the local interconnects 81a, 81b, 81c, and 81d and the portions 22a, 22b, 22c, and 22d in the active region 2P in the lower part. This can increase the capacitance value of the capacitor cell.

### Alteration 2

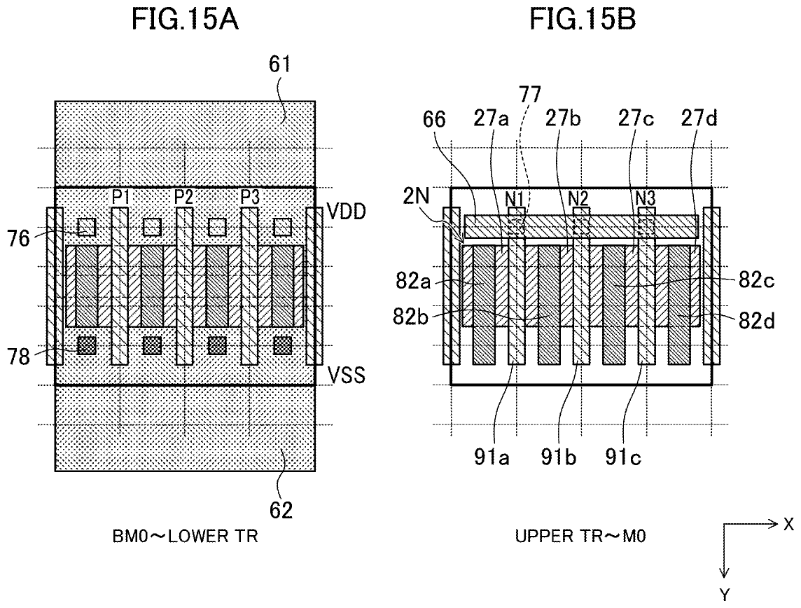

FIGS. 15A-15B are plan views showing a layout structure example of a capacitor cell according to Alteration 2 of this embodiment, in which FIG. 15A shows a lower part and FIG. 15B shows an upper part. The circuit diagram of the capacitor cell shown in FIGS. 15A-15B is the same as that of FIG. 10. That is, the n-type transistors N1, N2, and N3 form capacitors.

As shown in FIGS. 15A-15B, in the M0 interconnect layer, an interconnect 66 extending in the X direction is formed on the upper side of the active region 2N as viewed in the figure. The interconnect 66 is connected to the power supply line 61 in the BM0 interconnect layer through vias 76. The interconnect 66 is also connected to the gate interconnects 91a, 91b, and 91c through vias 77. With this, VDD is supplied from the power supply line 61 to the gate interconnects 91a, 91b, and 91c.

Also, the local interconnects 82a, 82b, 82c, and 82d in the upper part are connected to the power supply line 62 in the BM0 interconnect layer through vias 78. With this, VSS is supplied from the power supply line 62 to the portions 27a, 27b, 27c, and 27d serving as the sources or drains of the n-type nanosheet FETs in the active region 2N.

While, in the CFETs, the p-type transistors are formed in the lower part and the n-type transistors are formed in the upper part in the above embodiments, the conductivity types of the transistors formed may be the opposite. That is, n-type transistors may be formed in the lower part and p-type transistors may be formed in the upper part.

Also, in the above embodiments, in each of the capacitor cell and the inverter cells, the active region in the lower part and the active region in the upper part are the same in size and placement position in the Y direction. However, the configuration is not limited to this, but the active region in the lower part and the active region in the upper part may be different in size and placement position in the Y direction from each other. In this case, it is just required for the active regions in the upper parts, and the active regions in the lower parts, individually to have relationships in size and placement position like those described in the above embodiments.

While the inverter cells are used as an example of logic cell in the above embodiments, other logic cells, such as NAND cells, NOR cells, and flipflop cells, may be used.

While two different sizes, w1 and w2, are used as the sizes in the Y direction of the active regions of the logic cells in the above embodiments, three or more different sizes may be used. In this case, it is just required to set the size and placement position in the Y direction of the active regions of the capacitor cell in accordance with the maximum-sized active region, for example.

While the nanosheet FET is illustrated as having three sheets lying one above another and have a rectangular cross-sectional shape in the above embodiments, the number of sheets and cross-sectional shape of the nanosheet FET are not limited to these. Also, the number of sheets and cross-sectional shape of the nanosheet may be made different between the lower part and the upper part of the CFET.

According to the present disclosure, a layout structure of a capacitor cell using CFETs and back-side interconnects can be provided. The present disclosure is therefore useful for improving the performance of a semiconductor chip, for example.

1. A semiconductor integrated circuit device including a standard cell serving as a capacitor cell,
wherein
the standard cell includes
a first nanosheet field effect transistor (FET) of a first conductivity type including a first nanosheet extending in a first direction,
a second nanosheet FET of a second conductivity type formed above the first nanosheet FET in a depth direction, and including a second nanosheet extending in the first direction and overlapping the first nanosheet in planar view,
a gate interconnect extending in a second direction perpendicular to the first direction, overlapping the first and second nanosheets in planar view, and surrounding peripheries of the first and second nanosheets in the second direction and the depth direction,
a first power supply line formed in a first interconnect layer located on a back side of the first nanosheet FET, extending in the first direction, overlapping the first nanosheet FET in planar view, and supplying a first power supply voltage, and
a second power supply line connected to the gate interconnect and supplying a second power supply voltage, and
the first power supply line is connected to a source of the first nanosheet FET through first via provided at a position overlapping the first power supply line and the first nanosheet FET in planar view.

2. The semiconductor integrated circuit device of claim 1, wherein
the second power supply line is formed in a second interconnect layer located on a front side of the second nanosheet FET, extends in the first direction, and overlaps the second nanosheet FET in planar view.

3. The semiconductor integrated circuit device of claim 2, wherein
the second power supply line is connected to the gate interconnect through a second via provided at a position overlapping the second power supply line and the second nanosheet FET in planar view.

4. The semiconductor integrated circuit device of claim 3, wherein
the second via is placed at an end, in the second direction, of an overlap region of the second power supply line and the second nanosheet in planar view.

5. The semiconductor integrated circuit device of claim 3, wherein
the standard cell further includes
a first local interconnect connected to a source of the second nanosheet FET and extending in the second direction, and
the second power supply line is connected to the first local interconnect through a third via provided at a position overlapping the second power supply line and the first local interconnect in planar view.

6. The semiconductor integrated circuit device of claim 5, wherein
the standard cell further includes
a first interconnect formed in the second interconnect layer, extending in the first direction, and connected to the gate interconnect and the first local interconnect.

7. The semiconductor integrated circuit device of claim 1, wherein
the second power supply line is formed in the first interconnect layer, extends in the first direction, and overlaps the first nanosheet FET in planar view.

8. The semiconductor integrated circuit device of claim 7, wherein
the standard cell further includes
a first interconnect formed in a second interconnect layer located on a front side of the second nanosheet FET, overlaps the second power supply line in planar view, and connected to the gate interconnect, and
the second power supply line is connected to the first interconnect through a second via provided at a position overlapping the second power supply line and the first interconnect in planar view.

9. The semiconductor integrated circuit device of claim 7, wherein
the standard cell further includes
a first local interconnect connected to a source of the second nanosheet FET and extending in the second direction, and
a first interconnect formed in a second interconnect layer located on a front side of the second nanosheet FET and connected to the first local interconnect and the gate interconnect, and
the second power supply line is connected to the first local interconnect through a third via provided at a position overlapping the second power supply line and the first local interconnect in planar view.

10. A semiconductor integrated circuit device, comprising:
a first standard cell serving as a capacitor cell; and
second and third standard cells having a logical function, placed in a same cell row as the first standard cell,
wherein
the first standard cell includes
a first nanosheet field effect transistor (FET) of a first conductivity type including a first nanosheet extending in a first direction,
a second nanosheet FET of a second conductivity type formed above the first nanosheet FET in a depth direction, and including a second nanosheet extending in the first direction and overlapping the first nanosheet in planar view,
a gate interconnect extending in a second direction perpendicular to the first direction, overlapping the first and second nanosheets in planar view, and surrounding peripheries of the first and second nanosheets in the second direction and the depth direction,
a first power supply line formed in a first interconnect layer located on a back side of the first nanosheet FET, extending in the first direction, overlapping the first nanosheet FET in planar view, and supplying a first power supply voltage, and
a second power supply line connected to the gate interconnect and supplying a second power supply voltage,
the first power supply line is connected to a source of the first nanosheet FET through first via provided at a position overlapping the first power supply line and the first nanosheet FET in planar view,
the second standard cell includes
a third nanosheet FET of the first conductivity type, formed at a same position as the first nanosheet FET in the depth direction, and including a third nanosheet extending in the first direction,
the third standard cell includes
a fourth nanosheet FET of the first conductivity type, formed at a same position as the first nanosheet FET in the depth direction, and including a fourth nanosheet extending in the first direction,
the third nanosheet is the same in size in the second direction and also the same in placement range in the second direction as the first nanosheet, and
the fourth nanosheet is smaller in size in the second direction than the first nanosheet.

11. The semiconductor integrated circuit device of claim 10, wherein
the first nanosheet, the third nanosheet, and the fourth nanosheet are the same in the position of one end of the nanosheet in the second direction.

12. The semiconductor integrated circuit device of claim 10, wherein
the second standard cell includes
a fifth nanosheet FET of the second conductivity type formed at a same position as the second nanosheet FET in the depth direction and including a fifth nanosheet extending in the first direction,
the third standard cell includes
a sixth nanosheet FET of the second conductivity type formed at a same position as the second nanosheet FET in the depth direction and including a sixth nanosheet extending in the first direction,
the fifth nanosheet is the same in size in the second direction and also the same in placement range in the second direction as the second nanosheet, and
the sixth nanosheet is smaller in size in the second direction than the second nanosheet.

13. The semiconductor integrated circuit device of claim 12, wherein
the second nanosheet, the fifth nanosheet, and the sixth nanosheet are the same in the position of one end of the nanosheet in the second direction.

14. The semiconductor integrated circuit device of claim 10, wherein
the second power supply line is formed in a second interconnect layer located on a front side of the second nanosheet FET, extends in the first direction, and overlaps the second nanosheet FET in planar view.

15. The semiconductor integrated circuit device of claim 14, wherein
the second power supply line is connected to the gate interconnect through a second via provided at a position overlapping the second power supply line and the second nanosheet FET in planar view.

16. The semiconductor integrated circuit device of claim 15, wherein
the second via is placed at an end, in the second direction, of an overlap region of the second power supply line and the second nanosheet in planar view.

17. The semiconductor integrated circuit device of claim 15, wherein
the first standard cell further includes
a first local interconnect connected to a source of the second nanosheet FET and extending in the second direction, and
the second power supply line is connected to the first local interconnect through a third via provided at a position overlapping the second power supply line and the first local interconnect in planar view.

18. The semiconductor integrated circuit device of claim 10, wherein
the second power supply line is formed in the first interconnect layer, extends in the first direction, and overlaps the first nanosheet FET in planar view.

19. The semiconductor integrated circuit device of claim 18, wherein
the first standard cell further includes
a first interconnect formed in a second interconnect layer located on a front side of the second nanosheet FET, overlaps the second power supply line in planar view, and connected to the gate interconnect, and
the second power supply line is connected to the first interconnect through a second via provided at a position overlapping the second power supply line and the first interconnect in planar view.

20. The semiconductor integrated circuit device of claim 18, wherein
the first standard cell further includes
a first local interconnect connected to a source of the second nanosheet FET and extending in the second direction, and
a first interconnect formed in a second interconnect layer located on a front side of the second nanosheet FET, and connected to the first local interconnect and the gate interconnect, and
the second power supply line is connected to the first local interconnect through a third via provided at a position overlapping the second power supply line and the first local interconnect in planar view.
